(19) United States
(12) Patent Application Publication
(10) Pub. No.: US 2026/0301835 A1
(43) Pub. Date: Oct. 1, 2026

(54) ERROR SCAN FREQUENCY ADJUSTMENTS

(71) Applicant: Micron Technology, Inc., Boise, ID (US)

(72) Inventors: Li-Te Chang, San Jose, CA (US); Frederick Adi, Castro Valley, CA (US); Murong Lang, San Jose, CA (US)

(21) Appl. No.: 19/097,646

(22) Filed: Apr. 1, 2025

(51) Int. Cl. G11C 29/10

(52) U.S. Cl. CPC G11C 29/10

(57) ABSTRACT

Methods, systems, and devices for error scan frequency adjustments are described. A memory system may determine whether a quantity of error scans performed on one or more blocks of memory cells satisfies a threshold quantity of error scans. In some examples, in response to the quantity of error scans satisfying the threshold, the memory system may decrease the frequency of error scans to be performed on the blocks associated with the offset. In other examples, in response to the quantity of error scans failing to satisfy the threshold, the memory system may increase the frequency of error scans to be performed on the blocks associated with the offset. In response to adjusting the error scan frequency, the memory system may perform the error scans according to the adjusted error scan frequency.

### TECHNICAL FIELD

The following relates to one or more systems for memory, including error scan frequency adjustments.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports error scan frequency adjustments in accordance with examples as disclosed herein.

FIG. 2 shows an example of an architecture that supports error scan frequency adjustments in accordance with examples as disclosed herein.

FIG. 3 shows an example of a process that supports error scan frequency adjustments in accordance with examples as disclosed herein.

FIG. 4 shows a block diagram of a memory system that supports error scan frequency adjustments in accordance with examples as disclosed herein.

FIG. 5 shows a flowchart illustrating a method or methods that support error scan frequency adjustments in accordance with examples as disclosed herein.

### DETAILED DESCRIPTION

Some types of memory cells may experience voltage distribution shifts after being programmed due to charge loss (e.g., slow charge loss (SCL)) over time. To account for potential voltage distribution shifts associated with memory cells, a memory system may adjust voltages used in various access operations at the memory cells. For example, the memory system may perform one or more operations (e.g., one or more error correction and avoidance operations) to determine whether SCL has occurred at a memory cell. In response to detecting a voltage distribution shift at the memory cell, the memory system may adjust a read voltage associated with future read operations at the memory cell to account for the determined voltage distribution shift. For example, the memory system may add or remove an offset voltage to one or more read voltages. In some examples, the memory system may determine that multiple blocks of memory cells may be associated with a same voltage distribution shift (e.g., a same SCL), and may assign a same offset voltage to each of the blocks of memory cells.

The memory system may periodically (e.g., during background operations) refresh each block of memory cells to detect errors and thus increase read operation calibration efficacy. In some examples, the memory system may perform refresh operations (e.g., error scans) at blocks of memory cells at varying frequencies according to the assigned offsets. For example, a block of memory cells associated with a relatively large offset voltage may be associated with a relatively high error scan frequency (e.g., the block may be refreshed more often), and a block of memory cells associated with a relatively small offset voltage may be associated with a relatively low error scan frequency (e.g., the block may be refreshed less often). Although performing error scans may allow the memory system to detect read operation errors at the blocks of memory cells, an increase in error scan frequency may further increase SCL at the memory cells. For example, performing a relatively large quantity of error scans (e.g., within a short duration of time) on blocks of memory cells associated with a high SCL may increase SCL levels associated with the memory cells, thus increasing voltage distribution shift and decreasing efficiency of the memory system. Conversely, performing a low quantity of error scans on blocks of memory cells may lead to increased errors and may thus decrease the overall performance of the memory system.

To balance error scan frequency and mitigating SCL associated with blocks of memory cells, a memory system may implement dynamic error scan frequencies according to assigned offsets. For example, the memory system may determine whether a quantity of error scans performed on one or more blocks of memory cells (e.g., associated with an offset) satisfies a threshold quantity of error scans. In some examples, in response to the quantity of error scans satisfying the threshold (e.g., in response to the blocks being over-scanned), the memory system may decrease the frequency of error scans to be performed on the blocks associated with the offset. In other examples, in response to the quantity of error scans failing to satisfy the threshold (e.g., in response to the blocks being under-scanned), the memory system may increase the frequency of error scans performed on the blocks associated with the offset. In response to adjusting the error scan frequency, the memory system may perform the error scans according to the adjusted error scan frequency. By dynamically adjusting a frequency of error scans to be performed on a block of memory cells associated with an offset voltage, the memory system may optimize the frequency at which blocks of memory cells are scanned, which may improve the overall performance of the memory system.

In addition to applicability in memory systems as described herein, techniques for error scan frequency adjustments may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by balancing error scan frequency and SCL of memory cells which may extend the life of electronic devices and thereby reducing electronic waste, among other benefits.

Features of the disclosure are illustrated and described in the context of systems, devices, and circuits. Features of the disclosure are further illustrated and described in the context of architectures, processes, and flowcharts.

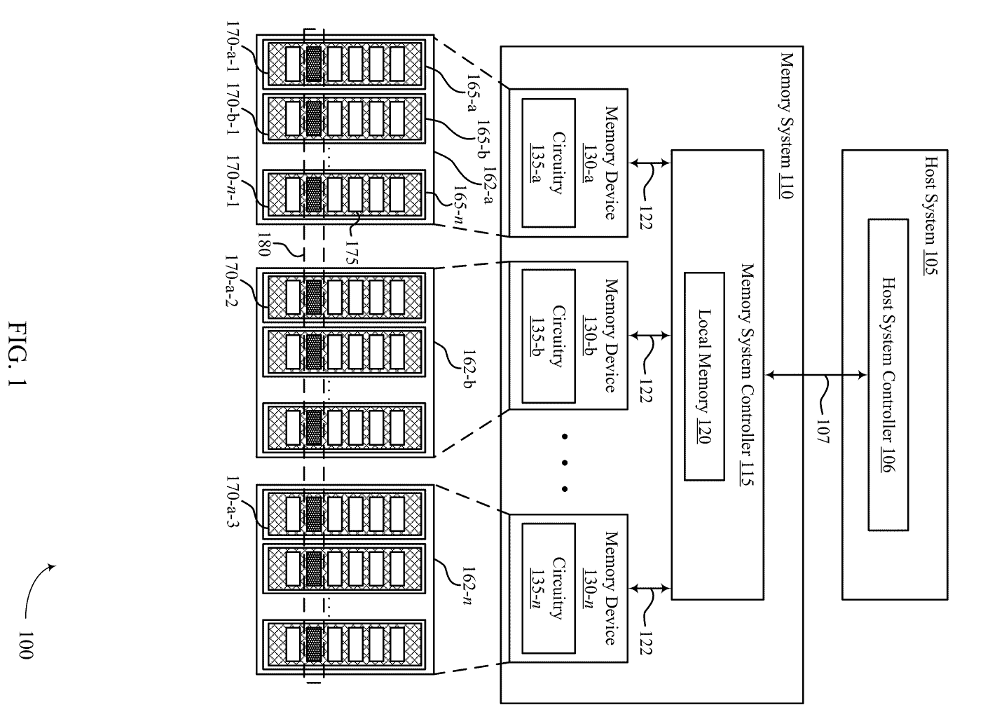

FIG. 1 shows an example of a system 100 that supports error scan frequency adjustments in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface 107 with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via an interface 107. The host system 105 and the memory system 110 may, in some cases, be configured to communicate via the interface 107 using an associated protocol (e.g., to exchange or otherwise communicate control, address, data, and other signals between the memory system 110 and the host system 105). Examples of the interface 107 may include, but are not limited to, a SATA interface, a UFS interface, an eMMC interface, a PCIe interface, a USB interface, a Fiber Channel interface, a SCSI, a Serial Attached SCSI (SAS) interface, a Double Data Rate (DDR) interface, a DIMM interface (e.g., DIMM socket interface that supports DDR), an Open NAND Flash Interface (ONFI), Mobile Industry Processor Interface (MIPI) Unified Protocol (UniPro), MIPI Physical (M-PHY) interface, and a Low Power Double Data Rate (LPDDR) interface. In some examples, multiple such interfaces 107 may be included in or otherwise supported between a host system controller 106 of the host system 105 and a memory system controller 115 of the memory system 110 (e.g., the interface 107 may support communication via multiple protocol layers such as UFS at an application layer, UniPro at a transport layer, and M-PHY at a physical layer).

The memory system 110 may include a memory system controller 115 and one or more memory devices 130. A memory device 130 may include one or more memory arrays of any type of memory cells (e.g., non-volatile memory cells, volatile memory cells, or any combination thereof). The memory system 110 may include memory devices 130-a, 130-b, up to 130-n, where n represents any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the interface 107) and may be an example of a controller or control component configured to cause the memory system 110 to perform various operations in accordance with examples as described herein. The memory system controller 115 may also be coupled with and communicate with memory devices 130 via respective interfaces 122 to perform operations such as reading data, writing data, erasing data, or refreshing data at a memory device 130—among other such operations—which may generically be referred to as access operations. In some examples, the respective interfaces 122 may be examples of single data rate (SDR) interfaces, DRR interfaces, ONFI interfaces, and the like. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include volatile memory (e.g., static random access memory (SRAM), dynamic random access memory (DRAM), or other memory) that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or respective circuitry 135, which may be internal to memory devices 130, respectively, to perform the functions ascribed herein to the memory system controller 115. In general, one or more functions ascribed herein to the memory system controller 115 may, in some cases, be performed instead by the host system 105, circuitry 135, or any combination thereof. For example, the circuitry 135 may be or include a microcontroller, special purpose logic circuitry (e.g., an FPGA, an ASIC, a DSP), or any other suitable processor or processing circuitry. Thus, in some instances, “processor” or “processing circuitry” may refer to functions performed by the memory system controller 115, the host system 105, the circuitry 135 of one or more memory devices 130, or any combination thereof. In some cases, a memory system 110 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as DRAM memory cells or SRAM memory cells.

In some examples, a memory device 130 may include (e.g., on the same die, within the same package) circuitry 135, which may execute or otherwise support operations on one or more memory cells of the respective memory device 130. Respective circuitry 135 may operate in conjunction with a memory system controller 115 or may perform one or more functions ascribed herein to the memory system controller 115. For example, as illustrated in FIG. 1, a memory device 130-a may include circuitry 135-a, a memory device 130-b may include circuitry 135-b, and a memory device 130-n may include circuitry 135-n.

In some cases, a memory device 130 may be or include a NAND device (e.g., NAND flash device). A memory device 130 may be or include a die 162 (e.g., a memory die). For example, in some cases, a memory device 130 may be a package that includes one or more dies 162. A die 162 may, in some examples, be a piece of electronics-grade semiconductor cut from a wafer (e.g., a silicon die cut from a silicon wafer). The memory cells for each die 162 may be arranged in one or more planes 165, and each plane 165 may include one or more blocks 170, where each block 170 may include one or more pages 175, and each page 175 may include a set of memory cells. In some examples, each die 162 may include n planes 165 and each plane may include m blocks 170, where n and m represent positive integers.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases concurrent operations may be performed on different planes 165 or on different blocks 170. For example, concurrent operations may be performed on memory cells within different blocks 170 so long as the different blocks 170 are in different planes 165. In some examples, each memory die 162 may include any quantity of planes 165. For example, the memory die 162-a may include a plane 165-a, a plane 165-b, and a plane 165-n, where n represents an Nth plane. The memory die 162-b and the memory die 162-n may also include N planes. In some cases, an individual block 170 may be referred to as a physical block, and a virtual block 180 may refer to a group of physical blocks 170 within which concurrent operations may occur. A virtual block 180 may be a logical structure that includes a plurality of blocks, where different blocks of the plurality of blocks may come from different planes 165 or different memory dies 162. In some cases, a virtual block may include blocks 170 from different memory devices 130 (e.g., including blocks in one or more planes 165 of memory device 130-a, memory device 130-b, and memory device 130-n). In some examples, a virtual block may include a respective block from each plane 165 (e.g., a block 170 from each plane 165) of one or more memory dies 162.

In some cases, the blocks 170 within a virtual block may have the same block address within their respective planes 165. For example, block 170-a-1 may be “block 0” of a first plane of die 162-a, block 170-a-2 may be “block 0” of a first plane of die 162-b, block 170-a-3 may be “block 0” of a first plane of die 162-n, and so on. By way of further example, block 170-b-1 may be “block 1” of a first plane of die 162-a and block 170-n1 may be “block n” of die 162-a, where n represents an Nth block. The memory die 162-b and the memory die 162-n may also include N blocks. In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). For example, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be restricted from being re-written with new data until they are erased. Thus, for example, an invalid page 175 may, in some cases, not be updated until the entire block 170 that includes the page 175 has been erased.

In some cases, to update some data within a block 170 while retaining other data within the block 170, the memory device 130 may write the updated data to a new block 170. The memory device 130 (e.g., circuitry 135) or the memory system controller 115 may mark or otherwise designate the addresses of the data that was updated in the block 170 as invalid or obsolete and may update a logical-to-physical (L2P) mapping table to associate the logical address (e.g., LBA) for the data with the new block 170 rather than the original block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by circuitry 135 or memory system controller 115.

In some cases, L2P mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system controller 115 or circuitry 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some examples, the memory cells of the blocks 170 may experience voltage distribution shifts after being programmed due to charge loss (e.g., slow charge loss (SCL)) over time. To account for potential voltage distribution shifts associated with memory cells, the memory system 110 may adjust voltages used in various access operations at the memory cells. For example, the memory system 110 may perform one or more operations (e.g., one or more error correction and avoidance operations) to determine whether SCL has occurred at a memory cell. In response to detecting a voltage distribution shift at the memory cell, the memory system 110 may adjust a read voltage associated with future read operations at the memory cell to account for the determined voltage distribution shift. For example, the memory system may add or remove an offset voltage to one or more read voltages. In some examples, the memory system 110 may determine that multiple blocks of memory cells may be associated with a same voltage distribution shift (e.g., a same SCL), and may assign a same offset voltage to each of the blocks of memory cells.

The memory system controller 115 may periodically (e.g., during background operations) refresh each block of memory cells to detect errors and thus increase read operation calibration efficacy. In some examples, the memory system controller 115 may perform refresh operations (e.g., error scans) at the blocks of memory cells associated at varying frequencies according to the assigned offsets. For example, a block of memory cells associated with a relatively large offset voltage may be associated with a relatively high error scan frequency (e.g., the block may be refreshed more often), and a block of memory cells associated with a relatively small offset voltage may be associated with a relatively- low error scan frequency (e.g., the block may be refreshed less often). Although performing error scans may allow the memory system controller 115 to detect read operation errors at the blocks of memory cells, an increase in error scan frequency may further increase SCL at the memory cells. For example, performing a relatively large quantity of error scans (e.g., within a short duration of time) on blocks of memory cells associated with a high SCL may increase SCL levels associated with the memory cells, thus increasing voltage distribution shift and decreasing efficiency of the memory system 110. Conversely, performing a low quantity of error scans on blocks of memory cells may lead to increased errors and may thus decrease the overall performance of the memory system 110.

To balance error scan frequency and mitigating SCL associated with blocks of memory cells, the memory system 110 may implement dynamic error scan frequencies according to assigned offsets. For example, the memory system controller 115 may determine whether a quantity of error scans performed on one or more blocks of memory cells (e.g., associated with an offset) satisfies a threshold quantity of error scans. In some examples, in response to the quantity of error scans satisfying the threshold (e.g., the blocks being over-scanned), the memory system controller 115 may decrease the frequency of error scans performed on the blocks associated with the offset. In other examples, in response to the quantity of error scans failing to satisfy the threshold (e.g., the blocks being under-scanned), the memory system controller 115 may increase the frequency of error scans to be performed on the blocks associated with the offset. In response to adjusting the error scan frequency, the memory system controller 115 may perform the error scans according to the adjusted error scan frequency. By dynamically adjusting a frequency of error scans to be performed on a block of memory cells associated with an offset voltage, the memory system may optimize the frequency at which blocks of memory cells are scanned, which may improve the overall performance of the memory system.

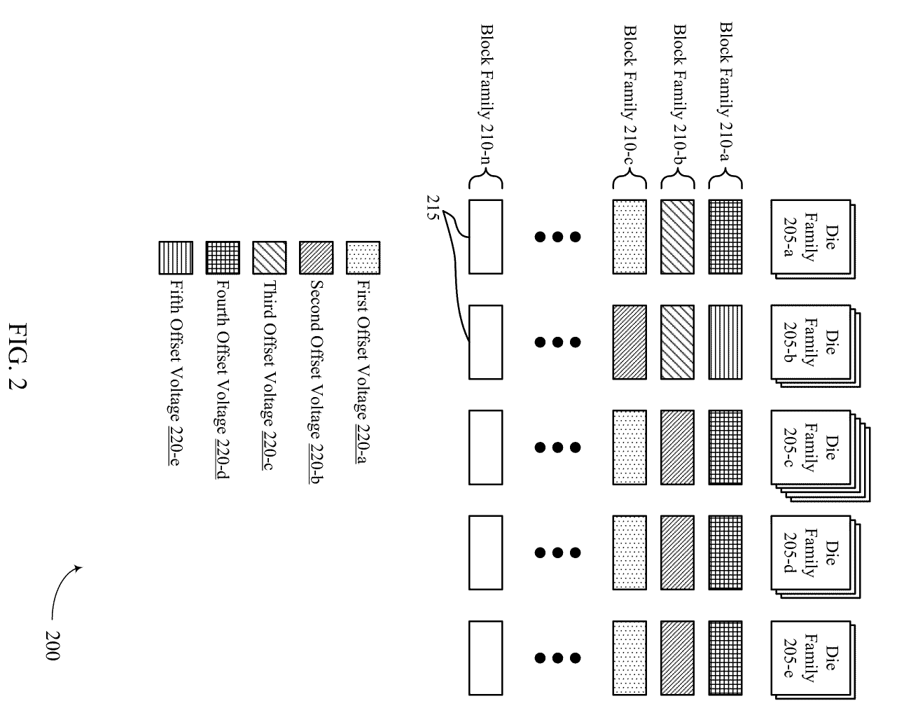

FIG. 2 shows an example of an architecture 200 that supports error scan frequency adjustments in accordance with examples as disclosed herein. The architecture 200 may include examples of a system 100 as described with reference to FIG. 1. For example, the architecture 200 illustrates a configuration of a memory device that includes blocks 215, block families 210, and die families 205, which may be examples of blocks 170, sets of the blocks 170, and sets of dies 162, respectively, as described herein with reference to FIG. 1. A memory system 110, as described herein with reference to FIG. 1, may store data according to the architecture 200, and a controller of the memory system (e.g., a memory system controller 115) may be configured to perform operations at the various components thereof.

The architecture 200 may be associated with a memory system that includes one or more memory devices (e.g., memory system 110 and memory devices 130, respectively, of FIG. 1). The architecture 200 may include one or more die families 205, which may each include one or more dies 162 as described with reference to FIG. 1. Each die family 205 may include one or more blocks 215, which may be examples of the blocks 170 as described with reference to FIG. 1. Each block 215 may include one or more memory cells, and may be associated with a block family 210. In some examples, each block family 210 may include multiple blocks 215 and may be associated with one or more of the die families 205. For example, the block family 210-a may include multiple blocks 215 of the die family 205-a, the die family 205-b, the die family 205-c, the die family 205-d, and the die family 205-e.

A controller of the memory system (e.g., memory system controller 115, as described with reference to FIG. 1) may perform one or more access operations and error correction operations at each of the blocks 215 of the architecture 200, as further described herein with reference to FIG. 1. To access a memory cell of a block 215, the memory system controller may apply an access voltage (e.g., a read voltage, a write voltage) to the memory cell. However, in some examples, the memory cell may experience a voltage distribution shift after being programmed due to charge loss (e.g., SCL) at the memory cell over time. To account for potential voltage distribution shifts associated with the memory cell, the memory system controller may adjust a voltage associated with future access operations at the memory cell. For example, the memory system controller may perform one or more error correction and avoidance operations to determine whether SCL has occurred at the memory cell. In response to detecting a voltage distribution shift at the memory cell, the memory system controller may adjust a read voltage associated with future read operations by adding or removing an offset voltage 220.

In some examples, the memory system controller may determine that multiple memory cells associated with different blocks 215 may be associated with a same voltage distribution shift (e.g., a same SCL), and may assign a same offset voltage 220 to each of the blocks 215. For example, the memory system controller may assign a first offset voltage 220-a to the memory cells of the blocks 215 of the block family 210-c associated with the die family 205-a, the die family 205-c, the die family 205-d, and the die family 205-e in response to detecting a first voltage distribution shift at the associated memory cells. Additionally, or alternatively, the memory system controller may assign a second offset voltage 220-b to the memory cells of the blocks 215 of the block family 210-c associated with the die family 205-b and to the memory cells of the blocks 215 of the block family 210-b associated with the die family 205-c, the die family 205-d, and the die family 205-e in response to detecting a second quantity of SCL at the associated memory cells. The memory system controller may also assign a third offset voltage 220-c to the memory cells of the blocks 215 of the block family 210-b associated with the die family 205-a and the die family 205-b; a fourth offset voltage 220-d to the memory cells of the blocks 215 of the block family 210-a associated with the die family 205-a, the die family 205-c, the die family 205-d, and the die family 205-e; and a fifth offset voltage 220-e to the memory cells of the blocks 215 of the block family 210-a associated with the die family 205-b.

As used herein, an offset voltage 220 (e.g., a read offset voltage) may refer to a voltage that may be added to or removed from a read voltage to read a memory cell. In some instances, the read offset voltage may be applied to read a memory cell having experienced a shift in voltage distribution such that the logic state of the memory cell may be accurately read (e.g., sensed). The offset voltages 220 may be associated with different voltages. For example, the first offset voltage 220-a may be an example of a largest offset voltage and the fifth offset voltage 220-e may be an example of a smallest offset voltage, respectively. However, in other examples, different offset voltages 220 may be relatively larger (or smaller) than others. Each of the offset voltages 220 may be stored to a look-up table (LUT) within the memory system. For example, to assign an offset voltage 220 to a block 215, the memory system controller may access the LUT and select an offset voltage 220 corresponding to a level of SCL associated with the block 215. In some examples, each offset voltage 220 may be an example of (e.g., associated with) a bin, which may be associated with a ratio of a trigger rate bit rate error rate (TR-RBER) to a time after program (TAP) (e.g., a quantity of time that passes after the associated memory cell is programmed). As used herein, a bin may refer to one or more read offsets (e.g., a set of read offsets) applied or otherwise assigned to a block family.

The memory system controller may periodically (e.g., during background operations) refresh each block 215 to detect errors and thus increase read operation calibration efficacy. In some examples, the memory system controller may perform refresh operations (e.g., error scans, quality of service (QoS) operations) at each of the blocks 215 at varying frequencies according to the assigned offset voltages 220. For example, a block 215 associated with a relatively large offset voltage (e.g., the first offset voltage 220-a) may be associated with a high error scan frequency (e.g., may be refreshed more often), and a block 215 associated with a relatively small offset voltage (e.g., the fifth offset voltage 220-e) may be associated with a low error scan frequency (e.g., may be refreshed less often). Performing error detection operations according to frequencies that are based on the offset voltages 220 may enable the memory system controller to frequently check for and adjust errors at memory cells experiencing a large quantity of SCL.

While performing error scans may allow the memory system controller to detect read operation errors at the blocks 215, an increase in error scan frequency may further increase SCL at the memory cells. For example, performing a large quantity of error scans (e.g., within a relatively short duration of time) on blocks 215 associated with a high SCL, such as the blocks 215 associated with a large offset voltage (e.g., the first offset voltage 220-a), may increase SCL levels associated with the memory cells, thus increasing voltage distribution shift and decreasing efficiency of the memory system. Additionally, or alternatively, performing a relatively low quantity of error scans on the blocks 215 (e.g., the blocks 215 associated with a large offset voltage) may lead to increased errors and may thus decrease the overall performance of the memory system.

To balance error scan frequency and SCL associated with each of the blocks 215, the memory system may implement dynamic error scan frequencies according to the assigned offset voltages 220. For example, the memory system controller may adjust a frequency of error scans associated with each of the offset voltages 220 based on determining whether a quantity of error scans previously-performed at associated blocks 215 satisfies a threshold quantity of error scans. In some examples, the memory system controller may determine whether a quantity of error scans performed at one or more of the blocks 215 has satisfied a threshold quantity of error scans. For example, in response to receiving a request to perform an error scan at one or more blocks 215 associated with the third offset voltage 220-c, the memory system controller may determine whether a quantity of error scans performed at the block 215 satisfies a threshold quantity of error scans.

In response to the quantity of error scans associated with the one or more blocks 215 satisfying the threshold (e.g., the blocks being relatively over-scanned), the memory system controller may decrease a frequency of future error scans to be performed on the one or more blocks 215 and other blocks 215 associated with the same offset voltage 220 (e.g., the third offset voltage 220-c). In some examples, to decrease the frequency of error scans, the memory system controller may decrease a quantity of error scans to be performed within a duration. In response to the quantity of error scans associated with one or more blocks 215 failing to satisfy the threshold (e.g., the blocks being relatively under-scanned), the memory system controller may increase the frequency of error scans to be performed on the one or more blocks 215 and other blocks 215 associated with the same offset voltage 220 (e.g., the third offset voltage 220-c). In some examples, to increase the frequency of error scans, the memory system controller may increase a quantity of error scans to be performed within a duration.

In response to adjusting the error scan frequency, the memory system controller may perform error scans according to the adjusted error scan frequency. For example, in response to receiving the request to perform an error scan at one or more blocks 215 associated with the third offset voltage 220-c, and based on adjusting the error scan frequency associated with the third offset voltage 220-c, the memory system controller may perform one or more error scan operations at the blocks 215 associated with the third offset voltage 220-c according to the updated error scan frequency.

By dynamically adjusting a frequency of error scans to be performed on the blocks 215 associated with an offset voltage 220, the memory system controller may perform an effective quantity of error scans on the blocks 215 while reducing a quantity of SCL that may have resulted from the blocks 215 being over-scanned. For example, adjusting the frequency of error scans based on a correlation between TR-RBER and TAP associated with the block 215 may enable the memory system to manage RBER associated with the respective block 215 in relation to a limit (e.g., a limit associated with a decoder of the memory system) and may thus reduce risks associated with TRs.

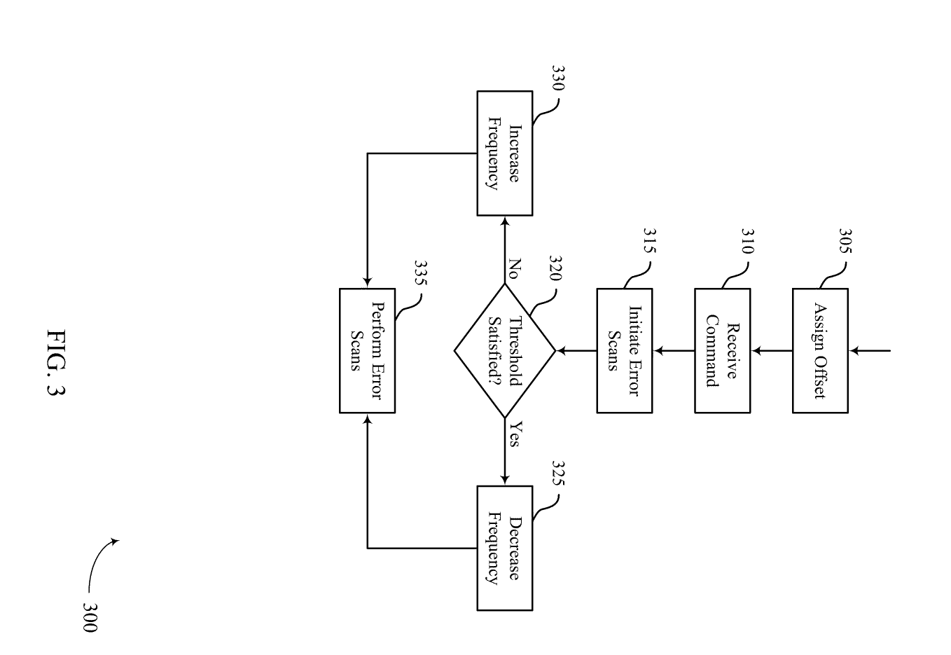

FIG. 3 shows an example of a process 300 that supports error scan frequency adjustments in accordance with examples as disclosed herein. The operations of the process 300 may be performed by a memory system or one or more controllers associated with a memory system as described herein. For example, the operations of process 300 may be performed by a memory system 110 or a controller thereof as described with reference to FIG. 1. The process 300 may also include reference to blocks, block families, and memory cells, which may be examples of blocks 170, blocks 215, and block families 210, respectively, as described with reference to FIGS. 1 and 2.

In the following description of the process 300, the operations may be performed in a different order than the order shown, or other operations may be added or removed from the process 300. For example, some operations may be left out of the process 300, may be performed in different orders or at different times, or other operations may be added to the process 300. Although a memory system is described as performing the process 300, some aspects of some operations may also be performed by one or more other memory systems, memory devices, host devices, controllers, or other electronic devices (e.g., as described herein with respect to FIGS. 1 and 2).

At 305, a memory system controller may assign an offset voltage. For example, the memory system controller may assign a first offset voltage (e.g., a first read offset voltage) value to a first block family. The first block family may include (e.g., be associated with) one or more blocks of memory cells that may be included in one or more memory dies. The memory system controller may assign offset voltages to one or more other block families, such that each block family may be associated with one or more offset voltages. Additionally, or alternatively, the first block family may be associated with a bin, which may be associated with one or more read offset values (e.g., offset voltages). In some examples, each offset voltage may be associated with a respective block of memory cells.

At 310, the memory system controller may receive a command. For example, based on assigning the first offset voltage to the first block family, the memory system controller may receive a command to initiate an error scan. In some examples, the command may include an indication that the memory system controller may initiate the error scan on blocks associated with the first offset voltage (e.g., the first read offset value).

At 315, the memory system controller may initiate one or more error scans. For example, in response to receiving the command, the memory system controller may initiate two or more error scans. In the case that the command may indicate the first offset voltage, the memory system controller may initiate an error scan on two or more block families (e.g., including the first block family) that are associated with the first offset voltage.

At 320, the memory system controller may determine whether a threshold has been satisfied. For example, based on receiving the command and initiating the error scans, the memory system controller may determine whether a quantity of previously performed error scans on a block of memory cells of the first block family satisfies a threshold quantity of error scans. The threshold quantity of error scans may be associated with an offset voltage value for reading at least the block of memory cells of the first block family.

The memory system controller may adjust a frequency of the error scans to be performed at the block of memory cells in response to determining whether the threshold has been satisfied. For example, if the memory system controller determines that the quantity of performed error scans associated with the block of memory cells satisfies the threshold quantity (e.g., to include a same or higher quantity of error scans as the threshold quantity), the memory system controller may decrease a frequency of error scans at 325. If the memory system controller determines that the quantity of performed error scans associated with the block of memory cells fails to satisfy the threshold quantity (e.g., to include a lower quantity of error scans than the threshold quantity), the memory system controller may increase a frequency of error scans at 330.

At 325, the memory system controller may decrease a frequency of error scans. For example, in response to the memory system controller determining that the quantity of performed error scans associated with the block of memory cells satisfies the threshold quantity (e.g., to include a same or higher quantity of error scans as the threshold quantity), the memory system controller may decrease a frequency of error scans to be performed at the block of memory cells (e.g., in the future). In some examples, decreasing the frequency of error scans to be performed on the block of memory cells may include the memory system controller decreasing a quantity of error scans to be performed within an upcoming duration.

At 330, the memory system controller may increase a frequency of error scans. For example, in response to the memory system controller determining that the quantity of performed error scans associated with the block of memory cells fails to satisfy the threshold quantity (e.g., to include a lower quantity of error scans than the threshold quantity), the memory system controller may increase a frequency of error scans to be performed at the block of memory cells (e.g., in the future). In some examples, increasing the frequency of error scans to be performed on the block of memory cells may include the memory system controller increasing a quantity of error scans to be performed within an upcoming duration.

At 335, the memory system controller may perform one or more error scans. For example, based on adjusting the frequency of the future error scans, the memory system controller may perform one or more error scans at the block of memory cells. The memory system controller may perform the one or more error scans at the block of memory cells according to the adjusted frequency of error scans.

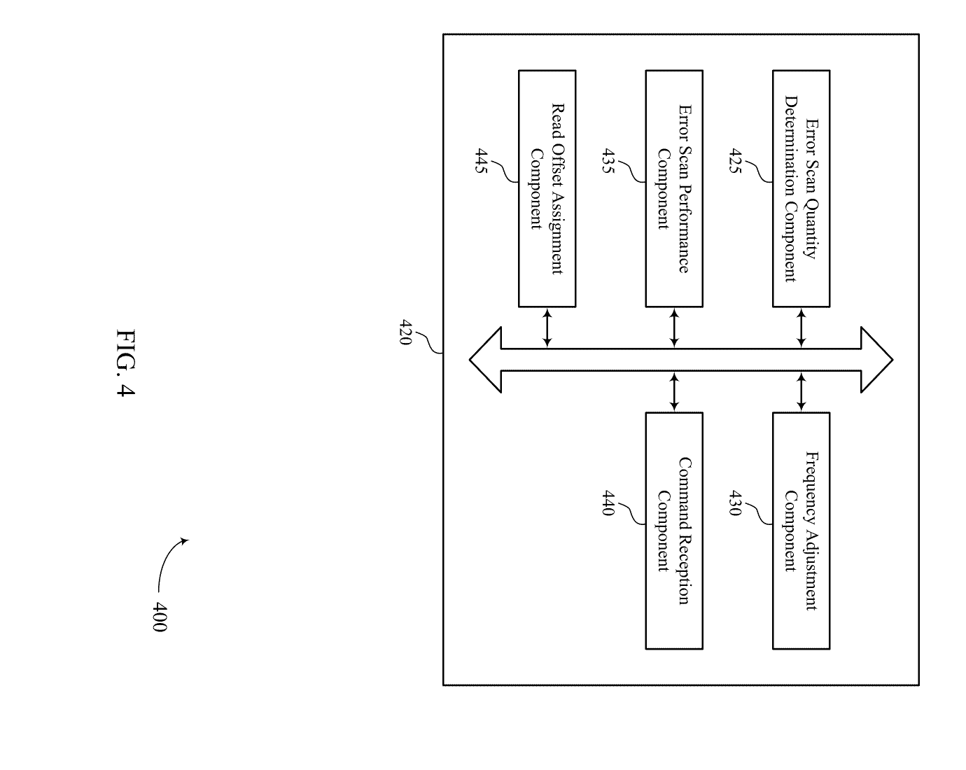

FIG. 4 shows a block diagram 400 of a memory system 420 that supports error scan frequency adjustments in accordance with examples as disclosed herein. The memory system 420 may be an example of aspects of a memory system as described with reference to FIGS. 1 through 3. The memory system 420, or various components thereof, may be an example of means for performing various aspects of error scan frequency adjustments as described herein. For example, the memory system 420 may include an error scan quantity determination component 425, a frequency adjustment component 430, an error scan performance component 435, a command reception component 440, a read offset assignment component 445, or any combination thereof. Each of these components, or components of subcomponents thereof (e.g., one or more processors, one or more memories), may communicate, directly or indirectly, with one another (e.g., via one or more buses).

The error scan quantity determination component 425 may be configured as or otherwise support a means for determining whether a quantity of error scans performed on a first block of memory cells satisfies a threshold value, the threshold value associated with a first read offset value for reading at least the first block of memory cells. The frequency adjustment component 430 may be configured as or otherwise support a means for adjusting, based at least in part on determining that the quantity of error scans satisfies the threshold value, a frequency of one or more error scans to be performed on the first block of memory cells. The error scan performance component 435 may be configured as or otherwise support a means for performing, based at least in part on adjusting the frequency of the one or more error scans, the one or more error scans on the first block of memory cells in accordance with the adjusted frequency.

In some examples, the frequency adjustment component 430 may be configured as or otherwise support a means for increasing, based at least in part on determining that the quantity of error scans fails to satisfy the threshold value after adjusting the frequency of the one or more error scans, a frequency of one or more second error scans to be performed on the first block of memory cells by increasing a quantity of second error scans performed within a duration. In some examples, the error scan performance component 435 may be configured as or otherwise support a means for performing, based at least in part on adjusting the frequency, the one or more second error scans on the first block of memory cells in accordance with the adjusted frequency.

In some examples, to support adjusting the frequency, the frequency adjustment component 430 may be configured as or otherwise support a means for decreasing the frequency of error scans to be performed on the first block of memory cells by decreasing the quantity of second error scans performed within the duration.

In some examples, the command reception component 440 may be configured as or otherwise support a means for receiving a command to initiate an error scan, where determining whether the quantity of error scans satisfies the threshold value is based at least in part on receiving the command. In some examples, the error scan performance component 435 may be configured as or otherwise support a means for initiating two or more error scans based at least in part on the command including an indication of the first read offset value, where determining whether the quantity of error scans performed on the first block of memory cells satisfies the threshold value is based at least in part on initiating the two or more error scans.

In some examples, each of the two or more error scans are performed on a respective block family that is associated with the first read offset value.

In some examples, the read offset assignment component 445 may be configured as or otherwise support a means for assigning the first read offset value to a first block family that includes the first block of memory cells, where receiving the command is based at least in part on assigning the first read offset value to the first block of memory cells.

In some examples, the first block family is associated with a plurality of blocks of memory cells that are included in one or more memory dies.

In some examples, the first block of memory cells is associated with a first bin including a plurality of read offset values; and each read offset value of the plurality of read offset values of the first bin is associated with a respective block of memory cells.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

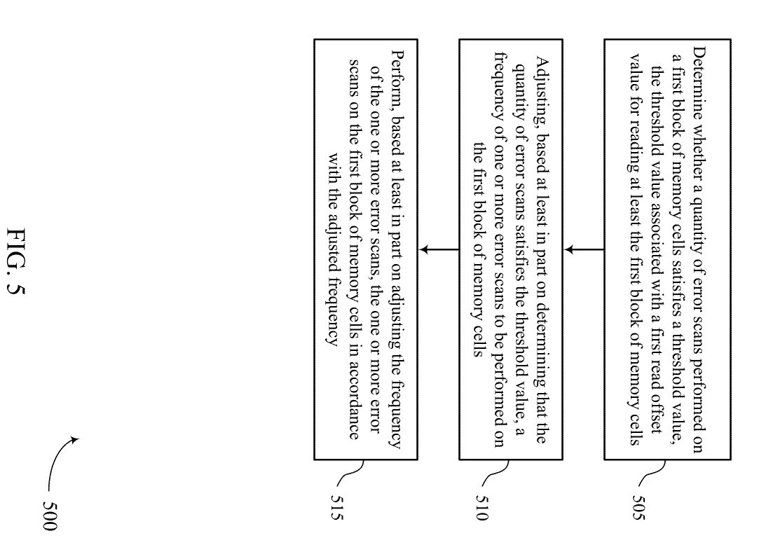

FIG. 5 shows a flowchart illustrating a method 500 that supports error scan frequency adjustments in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include determining whether a quantity of error scans performed on a first block of memory cells satisfies a threshold value, the threshold value associated with a first read offset value for reading at least the first block of memory cells. In some examples, aspects of the operations of 505 may be performed by an error scan quantity determination component 425 as described with reference to FIG. 4.

At 510, the method may include adjusting, based at least in part on determining that the quantity of error scans satisfies the threshold value, a frequency of one or more error scans to be performed on the first block of memory cells. In some examples, aspects of the operations of 510 may be performed by a frequency adjustment component 430 as described with reference to FIG. 4.

At 515, the method may include performing, based at least in part on adjusting the frequency of the one or more error scans, the one or more error scans on the first block of memory cells in accordance with the adjusted frequency. In some examples, aspects of the operations of 515 may be performed by an error scan performance component 435 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for determining whether a quantity of error scans performed on a first block of memory cells satisfies a threshold value, the threshold value associated with a first read offset value for reading at least the first block of memory cells; adjusting, based at least in part on determining that the quantity of error scans satisfies the threshold value, a frequency of one or more error scans to be performed on the first block of memory cells; and performing, based at least in part on adjusting the frequency of the one or more error scans, the one or more error scans on the first block of memory cells in accordance with the adjusted frequency.
Aspect 2: The method, apparatus, or non-transitory computer-readable medium of aspect 1, further including operations, features, circuitry, logic, means, or instructions, or any combination thereof for increasing, based at least in part on determining that the quantity of error scans fails to satisfy the threshold value after adjusting the frequency of the one or more error scans, a frequency of one or more second error scans to be performed on the first block of memory cells by increasing a quantity of second error scans performed within a duration and performing, based at least in part on adjusting the frequency, the one or more second error scans on the first block of memory cells in accordance with the adjusted frequency.
Aspect 3: The method, apparatus, or non-transitory computer-readable medium of any of aspects 1 through 2, where adjusting the frequency includes operations, features, circuitry, logic, means, or instructions, or any combination thereof for decreasing the frequency of error scans to be performed on the first block of memory cells by decreasing the quantity of second error scans performed within the duration.
Aspect 4: The method, apparatus, or non-transitory computer-readable medium of any of aspects 1 through 3, further including operations, features, circuitry, logic, means, or instructions, or any combination thereof for receiving a command to initiate an error scan, where determining whether the quantity of error scans satisfies the threshold value is based at least in part on receiving the command and initiating two or more error scans based at least in part on the command including an indication of the first read offset value, where determining whether the quantity of error scans performed on the first block of memory cells satisfies the threshold value is based at least in part on initiating the two or more error scans.
Aspect 5: The method, apparatus, or non-transitory computer-readable medium of aspect 4, where each of the two or more error scans are performed on a respective block family that is associated with the first read offset value.
Aspect 6: The method, apparatus, or non-transitory computer-readable medium of any of aspects 4 through 5, further including operations, features, circuitry, logic, means, or instructions, or any combination thereof for assigning the first read offset value to a first block family that includes the first block of memory cells, where receiving the command is based at least in part on assigning the first read offset value to the first block of memory cells.
Aspect 7: The method, apparatus, or non-transitory computer-readable medium of aspect 6, where the first block family is associated with a plurality of blocks of memory cells that are included in one or more memory dies.
Aspect 8: The method, apparatus, or non-transitory computer-readable medium of any of aspects 1 through 7, where the first block of memory cells is associated with a first bin including a plurality of read offset values; and each read offset value of the plurality of read offset values of the first bin is associated with a respective block of memory cells.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
processing circuitry associated with one or more memory devices and configured to cause the apparatus to:
determine whether a quantity of error scans performed on a first block of memory cells satisfies a threshold value, the threshold value associated with a first read offset value for reading at least the first block of memory cells;
adjusting, based at least in part on determining that the quantity of error scans satisfies the threshold value, a frequency of one or more error scans to be performed on the first block of memory cells; and
perform, based at least in part on adjusting the frequency of the one or more error scans, the one or more error scans on the first block of memory cells in accordance with the adjusted frequency.

2. The apparatus of claim 1, wherein the processing circuitry is further configured to cause the apparatus to:
increase, based at least in part on determining that the quantity of error scans fails to satisfy the threshold value after adjusting the frequency of the one or more error scans, a frequency of one or more second error scans to be performed on the first block of memory cells by increasing a quantity of second error scans performed within a duration; and
perform, based at least in part on adjusting the frequency, the one or more second error scans on the first block of memory cells in accordance with the adjusted frequency.

3. The apparatus of claim 2, wherein the frequency comprises a second quantity of error scans performed within a duration, wherein the processing circuitry is further configured to:
decrease the frequency of error scans to be performed on the first block of memory cells by decreasing the quantity of second error scans performed within the duration.

4. The apparatus of claim 1, wherein the processing circuitry is further configured to cause the apparatus to:
receive a command to initiate an error scan, wherein determining whether the quantity of error scans satisfies the threshold value is based at least in part on receiving the command; and
initiate two or more error scans based at least in part on the command comprising an indication of the first read offset value, wherein determining whether the quantity of error scans performed on the first block of memory cells satisfies the threshold value is based at least in part on initiating the two or more error scans.

5. The apparatus of claim 4, wherein each of the two or more error scans are performed on a respective block family that is associated with the first read offset value.

6. The apparatus of claim 4, wherein the processing circuitry is further configured to cause the apparatus to:
assign the first read offset value to a first block family that includes the first block of memory cells, wherein receiving the command is based at least in part on assigning the first read offset value to the first block of memory cells.

7. The apparatus of claim 6, wherein the first block family is associated with a plurality of blocks of memory cells that are included in one or more memory dies.

8. The apparatus of claim 1, wherein:
the first block of memory cells is associated with a first bin comprising a plurality of read offset values; and
each read offset value of the plurality of read offset values of the first bin is associated with a respective block of memory cells.

9. A method, comprising:
determining whether a quantity of error scans performed on a first block of memory cells satisfies a threshold value, the threshold value associated with a first read offset value for reading at least the first block of memory cells;
adjusting, based at least in part on determining that the quantity of error scans satisfies the threshold value, a frequency of one or more error scans to be performed on the first block of memory cells; and
performing, based at least in part on adjusting the frequency of the one or more error scans, the one or more error scans on the first block of memory cells in accordance with the adjusted frequency.

10. The method of claim 9, further comprising:
increasing, based at least in part on determining that the quantity of error scans fails to satisfy the threshold value after adjusting the frequency of the one or more error scans, a frequency of one or more second error scans to be performed on the first block of memory cells by increasing a quantity of second error scans performed within a duration; and
performing, based at least in part on adjusting the frequency, the one or more second error scans on the first block of memory cells in accordance with the adjusted frequency.

11. The method of claim 10, wherein the frequency comprises a second quantity of error scans performed within a duration, wherein adjusting the frequency comprises:
decreasing the frequency of error scans to be performed on the first block of memory cells by decreasing the quantity of second error scans performed within the duration.

12. The method of claim 9, further comprising:
receiving a command to initiate an error scan, wherein determining whether the quantity of error scans satisfies the threshold value is based at least in part on receiving the command; and
initiating two or more error scans based at least in part on the command comprising an indication of the first read offset value, wherein determining whether the quantity of error scans performed on the first block of memory cells satisfies the threshold value is based at least in part on initiating the two or more error scans.

13. The method of claim 12, wherein each of the two or more error scans are performed on a respective block family that is associated with the first read offset value.

14. The method of claim 12, further comprising:
assigning the first read offset value to a first block family that includes the first block of memory cells, wherein receiving the command is based at least in part on assigning the first read offset value to the first block of memory cells.

15. The method of claim 14, wherein the first block family is associated with a plurality of blocks of memory cells that are included in one or more memory dies.

16. The method of claim 9, wherein:
the first block of memory cells is associated with a first bin comprising a plurality of read offset values; and
each read offset value of the plurality of read offset values of the first bin is associated with a respective block of memory cells.

17. A non-transitory computer-readable medium storing code, the code comprising instructions executable by one or more processors to:
determine whether a quantity of error scans performed on a first block of memory cells satisfies a threshold value, the threshold value associated with a first read offset value for reading at least the first block of memory cells;
adjusting, based at least in part on determining that the quantity of error scans satisfies the threshold value, a frequency of one or more error scans to be performed on the first block of memory cells; and
perform, based at least in part on adjusting the frequency of the one or more error scans, the one or more error scans on the first block of memory cells in accordance with the adjusted frequency.

18. The non-transitory computer-readable medium of claim 17, wherein the instructions are further executable by the one or more processors to:
increase, based at least in part on determining that the quantity of error scans fails to satisfy the threshold value after adjusting the frequency of the one or more error scans, a frequency of one or more second error scans to be performed on the first block of memory cells by increasing a quantity of second error scans performed within a duration; and
perform, based at least in part on adjusting the frequency, the one or more second error scans on the first block of memory cells in accordance with the adjusted frequency.

19. The non-transitory computer-readable medium of claim 18, wherein the frequency comprises a second quantity of error scans performed within a duration, wherein the instructions to adjust the frequency are executable by the one or more processors to:
decrease the frequency of error scans to be performed on the first block of memory cells by decreasing the quantity of second error scans performed within the duration.

20. The non-transitory computer-readable medium of claim 17, wherein the instructions are further executable by the one or more processors to:
receive a command to initiate an error scan, wherein determining whether the quantity of error scans satisfies the threshold value is based at least in part on receiving the command; and
initiate two or more error scans based at least in part on the command comprising an indication of the first read offset value, wherein determining whether the quantity of error scans performed on the first block of memory cells satisfies the threshold value is based at least in part on initiating the two or more error scans.
